(19) United States
(12) Patent Application Publication
(10) Pub. No.: US 2004/0113047 A1
(43) Pub. Date: Jun. 17, 2004

(54) Image sensor module

(76) Inventor: Hsiu Wen Tu, Hsinchu Hsien (TW)

Correspondence Address: PRO-TECHTOR INTERNATIONAL, 20775 Norada Court, Saratoga, CA, 95070-3018, US

(21) Appl. No.: 10/321,906

(22) Filed: Dec. 16, 2002

(51) Int. Cl. H01L 27/00

(52) U.S. Cl. 250/208.1

(57) ABSTRACT

An image sensor module includes a lens holder, a lens barrel, and an image sensor. The lens holder has an upper end face, a lower end face and an opening penetrating through the lens holder from the upper end face to the lower end face. The lower end face is formed with a first engagement portion. The lens barrel is inserted from the upper end face of the lens holder and received within the opening. The image sensor has a first surface and a second surface opposite to the first surface on which a transparent layer is arranged. A second engagement portion is formed on the first surface out of a periphery of the transparent layer. The second engagement portion engages with the first engagement portion of the lens holder to fix the image sensor to the lower end face of the lens holder.

### BACKGROUND OF THE INVENTION

1. Field of the Invention

The invention relates to an image sensor module, and in particular to image sensor module that is easy to be assembled, disassembled and effectively positioned.

2. Description of the Related Art

Referring to FIG. 1, a conventional image sensor module includes a lens holder 10, a lens barrel 20, and an image sensor 30. The lens holder 10 has all upper end face 12, a lower end face 14 and an opening 16 penetrating through the lens holder 10 from the upper end face 12 to the lower end face 14. An internal thread 18 is formed on an inner wall of the opening 16 of the lens holder 10. The lens barrel 20 formed with an external thread 22 is inserted from the upper end face 12 of the lens holder 10, received within the opening 16, and screwed to the internal thread 18 of the lens holder 10. The lens barrel 20 is formed with a transparent region 24 under which an aspheric lens 26 and an infrared filter 28 are arranged in sequence. The image sensor 30 has a first surface 32 and a second surface 34 opposite to the first surface 32 on which a transparent layer 36 is arranged. The image sensor 30 is bonded to the lower end face 14 of the lens holder 10 through the transparent layer 36. The screwed length between the lens barrel 20 and the lens holder 10 may be adjusted to control the distance from the aspheric lens 26 of the lens barrel 20 to the transparent layer 36 of the image sensor 30.

The above-mentioned image sensor module has the following drawbacks.

1. Because the image sensor 30 is bonded to the lower end face 14 of the lens holder 10 through the transparent layer 36, the image sensor 30 cannot be replaced when the image sensor 30 of the module is damaged. In this case, the overall module has to be treated as waste material, and other good elements in the module may not be recycled.

2. Because the transparent layer 36 is bonded to the lower end face 14 of the lens holder 10 by the adhesive, which may contaminate the surface of the transparent layer 36, poor optical signals may be obtained.

3. When the module is assembled, the transparent layer 36 has to be precisely positioned with the aspheric lens 26 and then bonded to the lens barrel 20. Once the positional precision deviates from the standard level, the overall module cannot be reassembled and has to be treated as waste material

It is an important subject of the invention to provide an image sensor module, which is easy to be assembled, disassembled, and effectively positioned.

### SUMMARY OF THE INVENTION

An object of the invention is to provide an image sensor module, which is easy to be assembled and disassembled so as to facilitate the purpose of source recycling.

Another object of the invention is to provide an image sensor module for miniaturizing the product equipped therewith.

Still another object of the invention is to provide an image sensor module capable of precisely positioning so as to facilitate the manufacturing processes.

To achieve the above-mentioned objects, the invention provides an image sensor module including a lens holder, a lens barrel, and an image sensor. The lens holder has an upper end face, a lower end face and an opening penetrating through the lens holder from the upper end face to the lower end face. The lower end face is formed with a first engagement portion. The lens barrel is inserted from the upper end face of the lens holder and received within the opening. The image sensor has a first surface and a second surface opposite to the first surface on which a transparent layer is arranged. A second engagement portion is formed on the first surface out of a periphery of the transparent layer. The second engagement portion engages with the first engagement portion of the lens holder to fix the image sensor to the lower end face of the lens holder.

### BRIEF DESCRIPTION OF THE DRAWINGS

FIG. 1 is a schematic illustration showing a conventional image sensor module.

FIG. 2 is an exploded, cross-sectional view showing an image sensor module of the invention.

FIG. 3 is a cross-sectional view showing the image sensor module of FIG. 2.

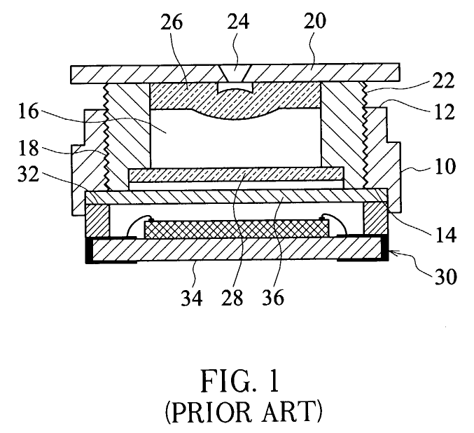

### DETAILED DESCRIPTION OF THE INVENTION

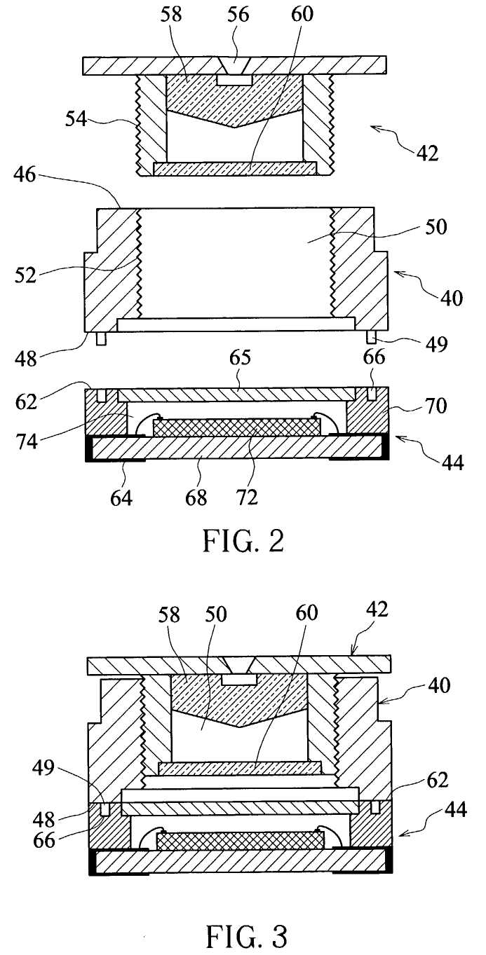

Referring to FIG. 2, an image sensor module of the invention includes a lens holder 40, a lens barrel 42 and an image sensor 44.

The lens holder 40 has an upper end face 46, a lower end face 48 and an opening 50 penetrating through the lens holder 40 from the upper end face 46 to the lower end face 48. An internal thread 52 is formed on an inner wall of the opening 50 of the lens holder 40, and the lower end face 48 of the lens holder 40 is formed with a first engagement portion 49. In this embodiment, the first engagement portion 49 may be a projection integrally formed with the lens holder 40.

The lens barrel 42 formed with an external thread 54 is inserted from the upper end face 46 of the lens holder 40, received within the opening 50, and screwed to the internal thread 52 of the lens holder 40. Thus, the positional relation between the lens barrel 42 and the lens holder 40 may be adjusted. The lens barrel 42 has a transparent region 56 under which an aspheric lens 58 and an infrared filter 60 are arranged in sequence.

The image sensor 44 has a first surface 62 and a second surface 64 opposite to the first surface 62 on which a transparent layer 65 is arranged. A second engagement portion 66, which may be engaged with the first engagement portion 49 of the lens holder 40 to precisely and conveniently fix the image sensor 44 to the lens holder 40, is formed on the first surface 62 out of the periphery of the transparent layer 65.

In this embodiment, the image sensor 44 includes a substrate 68, a frame layer 70, a photosensitive chip 72 and a transparent layer 65. The frame layer 70 is placed on the substrate 68 to form a cavity 74, which may accommodate the photosensitive chip 72, together with the substrate 68. In addition, the transparent layer 65 is placed on the frame layer 70. It should be noted that the second engagement portion 66 might be a recess formed on the frame layer 70.

As shown in FIG. 3, the first surface 62 of the image sensor 44 is pushed toward the lower end face 48 of the lens holder 40, and the second engagement portion 66 of the image sensor 44 may engage with the first engagement portion 49 of the lens holder 40. Accordingly, the image sensor 44 may be effectively and precisely fixed to the lens holder 40 through the engagement between the first and second engagement portions 49 and 66, thereby facilitating the precisely assembling processes. Then, the lens barrel 42 is screwed to the lens holder 40 and is positioned within the opening 50, and the distance from the transparent layer 65 to the aspheric lens 58 may be adjusted by way of adjusting the screwing length.

The image sensor module of the invention, in which the image sensor 44 and the lens holder 40 are combined by way of engagement, has the following advantages.

1. The image sensor 44 may be precisely combined with the lens holder 40 by precisely manufacturing the first engagement portion 49 and the second engagement portion 66 so as to facilitate the assembling processes.

2. If the image sensor 44 is not precisely positioned with the lens holder 40 after being assembled, the elements may be easily disassembled and reassembled. If one of the elements in the image sensor module is damaged, the damaged element may be easily disassembled and replaced, and a new element may be reassembled.

3. Because the image sensor 44 is combined with the lens holder 40 by way of engagement, the transparent layer 65 is free from being contaminated by the adhesive.

While the invention has been described by way of an example and in terms of a preferred embodiment, it is to be understood that the invention is not limited to the disclosed embodiment. To the contrary, it is intended to cover various modifications. Therefore, the scope of the appended claims should be accorded the broadest interpretation so as to encompass all such modifications.

What is claimed is:

1. An image sensor module, comprising:
a lens holder having an upper end face, a lower end face and an opening penetrating through the lens holder from the upper end face to the lower end face, the lower end face being formed with a first engagement portion;
a lens barrel inserted from the upper end face of the lens holder and received within the opening; and
an image sensor having a first surface and a second surface opposite to the first surface on which a transparent layer is arranged, wherein a second engagement portion is formed on the first surface out of a periphery of the transparent layer, and the second engagement portion engages with the first engagement portion of the lens holder to fix the image sensor to the lower end face of the lens holder.

2. The image sensor module according to claim 1, wherein the lens barrel is formed with a transparent region under which an aspheric lens is arranged.

3. The image sensor module according to claim 1, wherein the lens barrel is formed with an external thread, the opening of the lens holder is formed with an internal thread so that the lens barrel may be screwed to the lens holder and positioned within the opening.

4. The image sensor module according to claim 1, wherein the first engagement portion of the lens holder is a projection integrally formed with the lens holder, and the second engagement portion of the image sensor is a recess engaging with the projection.

5. The image sensor module according to claim 2, further comprising an infrared filter arranged in the lens barrel.

6. The image sensor module according to claim 1, wherein the image sensor comprises a substrate, a frame layer placed on the substrate, a photosensitive chip placed on the substrate and within the frame layer, and a transparent layer placed on the frame layer, and the second engagement portion is formed on the frame layer.
